(19) United States
(12) Patent Application Publication
(10) Pub. No.: US 2025/0220848 A1
(43) Pub. Date: Jul. 3, 2025

(54) DEVICE INCLUDING ACTIVE AIR-MOVING DEVICE WITH POP-OUT MODE FOR IMPROVED COOLING AND RELATED METHODS

(71) Applicant: QUALCOMM Incorporated, San Diego, CA (US)

(72) Inventors: Saju Cheeran Verghese Francis, Bangalore (IN); Shankar Gopalakrishna, Bengaluru (IN); Dhinesh Jambai Gopu, Bengaluru (IN)

(21) Appl. No.: 18/403,183

(22) Filed: Jan. 3, 2024

(51) Int. Cl. H05K 7/20

(52) U.S. Cl. CPC H05K 7/20172; H05K 7/20145; H05K 7/20154

(57) ABSTRACT

An air-moving device (AMD) disposed within a device housing creates airflow to dissipate heat from the device. To avoid internal airflow impedance experienced by the AMD, a device comprising an integrated circuit (IC) package and an AMD operates in a first mode wherein the AMD is disposed in a space inside a housing of the device and in a second mode wherein the AMD is outside the housing. In the second mode, the AMD is moved out of a space that is part of the airflow path inside the housing to substantially improve the rate of airflow, which can significantly increase a rate of heat dissipation from the device. In some examples, the AMD may be a fan having fins or blades that rotate in a plane of the housing, and in the second mode, the AMD remains in the same plane as it moves outside the housing through a side face.

### BACKGROUND

### I. Field of the Disclosure

The technology of the disclosure relates generally to power management in a multi-core processor and, more particularly, to improving performance while reducing power consumption in idle cores in a cluster in a multi-core processor.

### II. Background

Performance requirements for smartphones and other electronic devices continue to increase. These demands are met with increases in the number of transistors in a processor and the frequency of operation of the processor, causing an increase in the amount of heat generated within the device. This creates a corresponding demand for continuous improvements in thermal management and the development of new cooling methods to keep the transistor circuits from overheating and to keep the temperatures of user electronics (e.g., hand-held devices) at a level comfortable to the users. The use of graphite heat spreader sheets, heat pipes, and other passive cooling techniques have become more commonplace in electronic devices for improved cooling but may not be sufficient in the future. There are currently very few gaming devices using electric air-moving devices (e.g., fans/blowers) and other types of active mechanisms for cooling. Since gaming devices require extensive video streaming and high levels of graphics performance, improvements in airflow rate (e.g., cubic centimeters per minute) of an air-moving device (AMD) would significantly help to reduce circuit and device temperatures. AMDs are, in general, operating non-linearly, depending on the static pressure (air impedance effects), delivering more airflow when there are fewer obstructions on its flow path. However, given the current practice of packaging electronics as densely to achieve the smallest form factor possible (e.g., smartphones), improving internal airflow for cooling such devices is challenging.

### SUMMARY

Aspects disclosed in the detailed description include a device including an air-moving device with a pop-out mode for improved cooling. Related methods of cooling components inside a device with an air-moving device are also disclosed. In user devices, some applications can cause a processor in an integrated circuit (IC) package to operate at a higher-performance level for long periods of time, significantly heating the IC package. To avoid temperature increases that damage electronic components therein, the device may need to dissipate heat at a higher rate than is possible by passive cooling alone. Air-moving devices (AMDs) disposed within the device housing create airflow to dissipate heat from the device faster. However, the components within such devices are densely packed to minimize package size, significantly impeding airflow around the components. An AMD disposed in the airflow path may also experience the internal airflow impedance. In an exemplary aspect, a device comprising an IC package and an AMD operates in a first mode in which the AMD is disposed in a space inside a housing of the device and in a second mode in which the AMD is at least partially, if not entirely, outside the housing. In the second mode, the AMD is moved out of a space that is part of the airflow path inside the housing to substantially improve the rate of airflow, which can significantly increase a rate of heat dissipation from the device. In some examples, the AMD may be a fan having fins or blades that rotate in a plane of the housing, and in the second mode, the AMD remains in the same plane as it moves outside the housing through a side face.

In this regard, in one exemplary aspect, a device is disclosed. The device includes a housing, at least one IC package disposed inside the housing, and a first AMD configured to move air through the housing. In a first operating mode, the first AMD is disposed inside the housing, and in a second operating mode, the first AMD is disposed at least partially outside the housing.

In another exemplary aspect, a method of cooling a device is disclosed. The device includes at least one integrated circuit package in a housing, and a first air-moving AMD configured to move air through a first side face. The method includes, in a first operating mode, activating the AMD inside the housing and, in a second operating mode, moving the AMD at least partially outside the housing.

In another exemplary aspect, a smartphone is disclosed. The smartphone includes a housing including a front face and a back face opposite to each other, and a first side face between a first edge of the front face and a second edge of the back face. The smartphone further includes at least one IC package disposed inside the housing, the IC package including a processor configured to execute user applications, and a first air-moving AMD configured to move air through the first side face. In a first operating mode, the first AMD is disposed inside the housing; and in a second operating mode, the first AMD is disposed at least partially outside the housing.

### BRIEF DESCRIPTION OF THE DRAWINGS

FIG. 1A is a perspective view of an electronic device, such as a smartphone, including an air-moving device (AMD) internal to the device for cooling electronic components within the device in a first operating mode and FIG. 1B is a perspective view of the same electronic device in a second operating mode with the AMD external to the device housing for improved cooling;

FIG. 2A is an illustration of the interior of a portion of the electronic device in FIG. 1A to show internal components that are cooled by the AMD, and FIG. 2B is an illustration of the interior of the device shown in FIG. 1B in a second operating mode for increased airflow rate to improve internal component cooling;

FIG. 3 is a flowchart of a method of active cooling of electronic components in a device, including a pop-out mode of an AMD to increase airflow;

FIG. 4 is an illustration of another example of a device comprising an AMD outside a housing to push air into an inlet port of an airflow path and an exit AMD outside an outlet port configured to draw air out of the airflow path through an outlet port;

FIGS. 5A and 5B are views of another example of an electronic device including an AMD in a second operating mode where a protective grill is included on the AMD to avoid interference, such as with fins or blades of the AMD;

FIG. 6 is a block diagram of an exemplary wireless communication device that includes an AMD in a pop-out mode for increased airflow rate to improve internal component cooling, such as any of the electronic devices of FIGS. 1A, 1B, 2A, 2B, and 4; and

FIG. 7 is a block diagram of an exemplary processor-based system in an electronic device, including an AMD in a pop-out mode for increased airflow rate to improve internal component cooling, such as any of the electronic devices of FIGS. 1A, 1B, 2A, 2B, and 4.

### DETAILED DESCRIPTION

Several exemplary aspects of the present disclosure are described in reference to the drawing figures. The word “exemplary” is used herein to mean “serving as an example, instance, or illustration.” Any aspect described herein as “exemplary” is not necessarily to be construed as preferred or advantageous over other aspects.

Aspects disclosed in the detailed description include a device including an air-moving device with a pop-out mode for improved cooling. Related methods of cooling components inside a device with an air-moving device are also disclosed. In user devices, some applications can cause a processor in an integrated circuit (IC) package to operate at a higher-performance level for long periods of time, significantly heating the IC package. To avoid temperature increases that damage electronic components therein, the device may need to dissipate heat at a higher rate than is possible by passive cooling alone. Air-moving devices (AMDs) disposed within the device housing create airflow to dissipate heat from the device faster. However, the components within such devices are densely packed to minimize package size, significantly impeding airflow around the components. An AMD disposed in the air flow path may also experience the internal air flow impedance. In an exemplary aspect, a device comprising an IC package and an AMD operates in a first mode in which the AMD is disposed in a space inside a housing of the device and in a second mode in which the AMD is at least partially, if not entirely, outside the housing. In the second mode, the AMD is moved out of a space that is part of the airflow path inside the housing to substantially improve the rate of airflow, which can significantly increase a rate of heat dissipation from the device. In some examples, the AMD may be a fan having fins or blades that rotate in a plane of the housing and, in the second mode, the AMD remains in the same plane as it moves outside the housing through a side face.

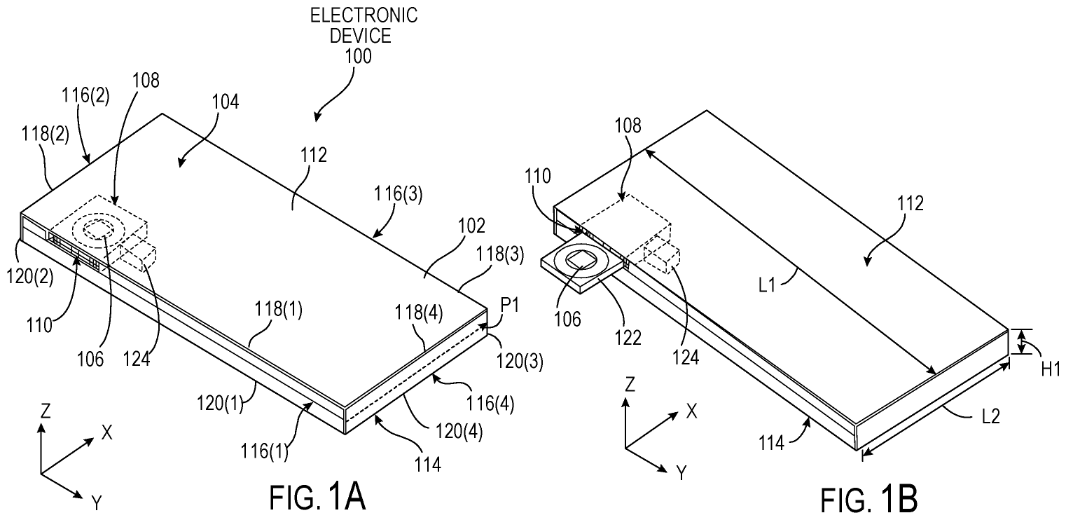

FIG. 1A is a perspective view of a device 100 in which a housing 102 contains at least one IC package 104, including electronic components and/or circuits that are configured to perform various user functions, such as telecommunications, graphics, social media, and gaming applications, for example. The device 100 may be, for example, a hand-held gaming device, a smartphone, a laptop, a tablet, etc., in which a processor(s) or processor executes application instructions. Since the device 100 may be any of such devices, specific features (e.g., video display, speaker, microphone, keypad, button, switch, knob, etc.) that may be included in the device 100 are not shown here. The IC package 104 may be disposed in one or more IC packages. As the processor executes application instructions, the IC package 104 generates heat, increasing the temperature inside the housing 102. For this reason, the device 100 includes an air-moving device (AMD) 106, which may be a fan or blower disposed in a space 108 inside the housing 102. In a first operation mode of the device 100, the AMD 106 is configured to pull or draw air into the housing 102 through an inlet port 110, force the air past the heated IC package 104, where some of the heat is transferred to the air, and force the heated air out of the housing 102 through an outlet port (not shown).

A second operation mode of the device 100 is described with reference to FIG. 1B. First, however, the device 100 is described in more detail with continued reference to FIG. 1A. The housing 102 includes a first, front face 112 and a second, back face 114 opposite to the front face 112. The front face 112 and the back face 114 may be parallel to each other. The housing 102 includes side faces 116(1)-116(4) that extend between edges 118(1)-118(4) of the front face 112 and edges 120(1)-120(4) of the back face 114. The side faces 116(1)-116(4) may be orthogonal to the front and back faces 112, 114. Although not shown in this example, the side faces 116(1)-116(4), and corners may be curved or rounded for user comfort and/or grip. The front and back faces 112, 114 may be rectangular, as shown in this example, such that a shape of the housing 102 may be a rectangular cuboid where the side faces 116(1) and 116(3) have a first length L1 in a first direction (Y-axis direction) and the side faces 116(2) and 116(4) have a second length L2 in a second direction (X-axis direction) orthogonal to the first direction. Because L1 is greater than L2 in this example, the side faces 116(1) and 116(3) may be referred to as “longer sides 116(1), 116(3)” and the side faces 116(2) and 116(4) may be referred to as “shorter sides 116(2), 116(4).” The side faces 116(1)-116(4) of the housing 102 have a height H1 in a third direction (Z-axis direction) orthogonal to the first and second directions. The first length L1 may be in a range from 4 inches to 12 inches and the second length L2 may be in a range from 2 inches to 9 inches, for example.

The AMD 106 is disposed in the space 108 inside the housing 102 adjacent to the side face 116(1) and the inlet port 110. That is, the space 108 may be immediately inside the inlet port 110. The AMD is configured to draw air into the inlet port 110 and force the air in a direction orthogonal to the side face 116(1) (e.g., X-axis direction) into an airflow path (not shown) inside the housing 102. However, with the AMD 106 disposed just inside the inlet port 110, the AMD 106 delivers air flow against the impedance into the inlet port 110. For example, the AMD 106 may be a fan or blower having blades or fins that rotate in a plane P1 (including the X-axis and the Y-axis) extending through the housing 102.

As shown in FIG. 1B, the device 100 also employs a second operating mode, which may also be referred to herein as a “pop-out mode,” in which the AMD 106 is positioned outside the inlet port 110 to significantly reduce impedance to the air flowing into the AMD 106 and through the space 108. That is, in the pop-out mode, the AMD 106 may draw air from outside the housing 102 in a direction orthogonal to the plane P1 of rotation without the restriction imposed by the front face 112 and the back face 114. In this mode, the AMD 106 can more easily push or force the air in the X-axis direction into the inlet port 110, providing increased airflow for cooling the IC packages 104 compared to the first operating mode shown in FIG. 1A.

The AMD 106 may be disposed on a slide or carrier 122 that moves the AMD 106 out of the space 108 and back into the space 108 through the inlet port 110. Movement of the carrier 122 into and out of the space 108 may be provided by a motor or controller (not shown) that is activated in response to any one of a plurality of triggers including a detected temperature or combination of temperatures (e.g., based on an algorithm), an instruction executed by a processor in the IC package 104, a user contact, action or force, and/or a mechanical device, such as a spring. That is, the device 100 may transition between the first operating mode, in which the AMD 106 is inside the housing 102, and a second operating mode, in which the AMD 106 is outside the housing 102, in response to any of the plurality of triggers described above.

In an alternative example, the slide or carrier 122 may move the AMD 106 out of the space 108 in the Z-axis direction in FIGS. 1A and 1B. That is, rather than moving the AMD 106 through the inlet port 110, a portion of the front face 112 or back face 114 may be displaced to allow the AMD 106 to pop out in a direction orthogonal to the plane P1.

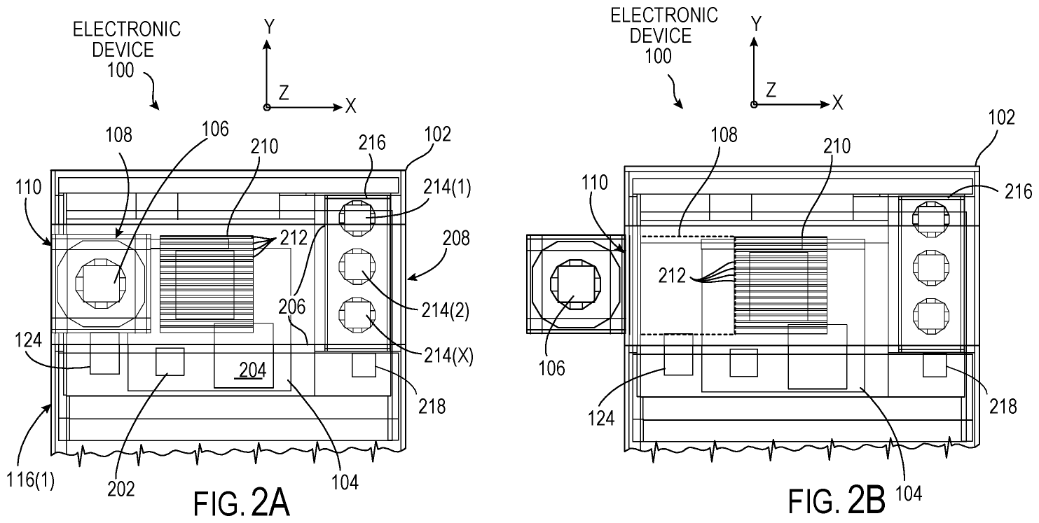

FIG. 2A is a partial view of the device 100, showing the interior beneath the front face 112 shown in FIG. 1A. Features of FIG. 2A previously shown in FIG. 1A are labeled the same in FIG. 2A. As discussed above, the device 100 includes an IC package 104, including electronic components and/or IC dies 202 and 204, which may include one or more processors for executing user applications. The IC package 104 is disposed in an airflow path 206 between the inlet port 110 and an outlet port 208. The AMD 106 is disposed in the space 108 adjacent to the side face 116(1) inside the housing 102. Air flow into the AMD 106 may be impeded in the space 108, which is bounded above and below by the front face 112 and the back face 114 (see FIG. 1A), respectively. The AMD 106 forces air away from the space 108 in a direction orthogonal to the side face 116(1) along the airflow path 206.

To improve heat dissipation from the IC package 104, a heat sink 210 comprising fins 212 is disposed on or in thermal contact with the IC package 104 and in the airflow path 206 in this example. Accordingly, heat generated in the IC package 104 is thermally conducted to the heat sink 210 including the fins 212. Air that is forced through the airflow path 206 by the AMD 106 is heated as it passes over the fins 212, and the heat is removed from the housing 102 as the air exits through the outlet port 208.

In this example, the device 100 also includes exit AMDs 214(1)-214(X), which may be similar to the AMD 106. In some examples, the device 100 comprises a single exit AMD 214(1), and in other examples, the number X of exit AMDs 214(1)-214(X) may be determined by available space within the housing 102. In the example shown here, X=3. In some examples, the exit AMDs 214(1)-214(X) may all be activated simultaneously, and in other examples, the exit AMDs 214(1)-214(X) may be individually controlled to provide a variable rate of air flow out of the outlet port 208. In some examples, the exit AMDs 214(1)-214(X) may be controlled separately from the AMD 106 or together with the AMD 106. Thus, the device 100 may include an operating mode in which the AMD 106 is inside the space 108 and at least one of the exit AMDs 214(1)-214(X) is outside the housing 102. In other examples, the device 100 may include an operating mode in which the AMD 106 is outside the space 108 and one or more of the exit AMDs 214(1)-214(X) are inside the housing 102. In some examples, multiple AMDs may be implemented on the inlet port 110 instead of the AMD 106.

As noted above, having the AMD 106 disposed inside the housing 102 in the space 108, in the first operating mode shown in FIG. 2A, may impede airflow through the airflow path 206. FIG. 2B shows the device 100 in the second operating mode with the AMD 106 disposed entirely outside the housing 102, after being moved through the inlet port 110. In some examples, the AMD 106 could be moved partially outside of the inlet port to provide a smaller improvement in air flow into the AMD 106. In the second operating mode, airflow into the AMD 106 is unobstructed, and airflow through the space 108 is increased. Accordingly, the amount of air that passes over the fins 212 increases with respect to the first operating mode. An effect of the increased airflow is an increased rate of cooling of the IC package 104, which helps to keep the temperature of the IC package 104 below a threshold. The threshold may be based on a temperature at which the heat could damage the components and/or circuits therein or on a level of comfort for a user holding the device 100, particularly in hand-held devices such as smartphones. Thus, the AMD 106 may be moved from inside the space 108 in the first operating mode to being outside the housing 102 in the second operating mode based on a temperature-activated mechanism, such as a motor. Alternatively, activation of certain applications may activate such mechanism. In another example, user contact may activate the mechanism or provide mechanical pressure causing the AMD 106 to pop out, in a spring-loaded manner, for example. Other triggers and/or mechanisms for moving the AMD 106 into or out of the housing 102 are also available.

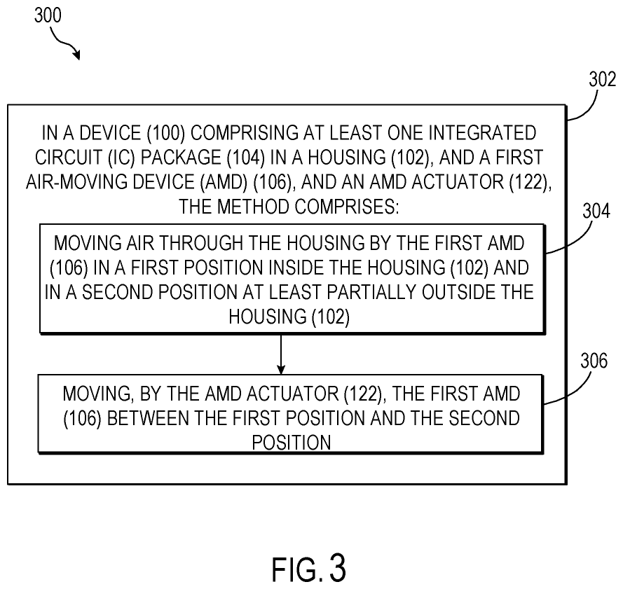

FIG. 3 is a flowchart of a method 300 of cooling a device 100. In a device 100 comprising at least one integrated circuit (IC) package 104 in a housing 102, a first air-moving device (AMD) 106 is configured to move air through the housing 102 (block 302). In a first operating mode, the AMD 106 is activated inside the housing 102 (block 304), and in a second operating mode, the AMD 106 is moved at least partially outside the housing 102 (block 306).

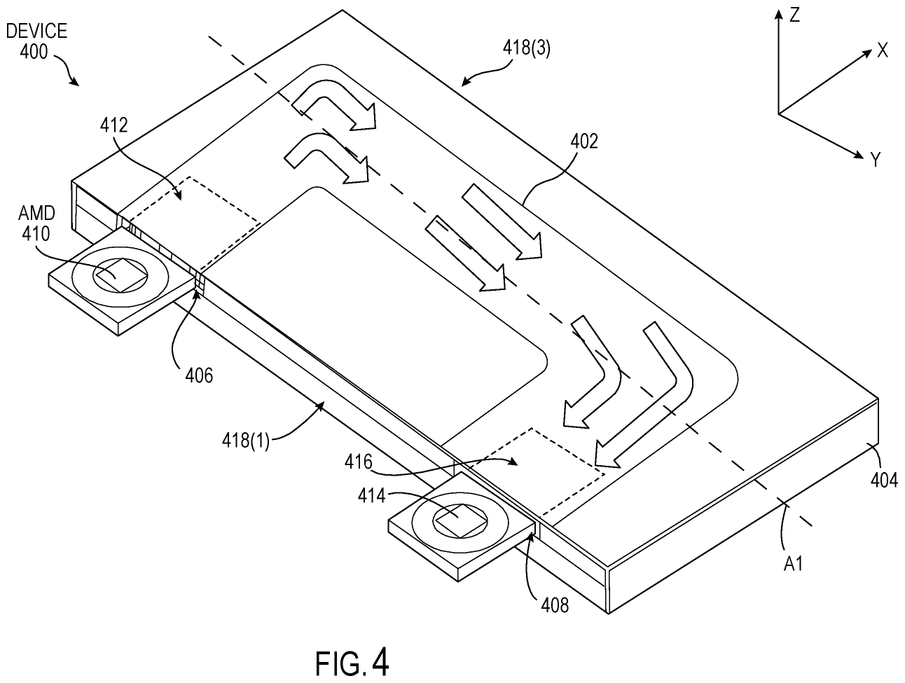

FIG. 4 is an illustration of another example of a device 400 comprising an airflow path 402 for removing heat from inside a housing 404. The housing 404 includes an inlet port 406 into the airflow path 402 and an outlet port 408 from the airflow path 402. The device 400 also includes an AMD 410 to push air through the airflow path 402. In the operating mode shown in FIG. 4, the AMD 410 is disposed outside of the inlet port 406 to reduce impedance of the airflow through the airflow path 402 but the AMD 410 may be in a space 412 inside the housing 404 and adjacent to the inlet port 406 in another operating mode. The device 400 also includes an exit AMD 414 configured to pull air through the airflow path 402. In the operating mode illustrated in FIG. 4, the exit AMD 414 is disposed outside of the outlet port 408 to reduce impedance of the airflow through the airflow path 402. In another operating mode, the exit AMD 414 may be disposed in a space 416 just inside the housing 404 and adjacent to the outlet port 408. In this example, rather than the airflow path 402 extending across the housing in the X-axis direction in FIG. 4 from a first longer side face 418(1) to a second longer side face 418(3), the inlet port 406 and the outlet port 408 are on the same side face 418(1). From the inlet port 406, the airflow path 402 turns and extends along a longitudinal axis A1 of the device 400 in the Y-axis direction, then turns again to the outlet port 408. In this airflow path 402, air flows through more of the housing 404 than in the device 100 in FIGS. 1A, 1B, 2A, and 2B, cooling a larger portion of the device 400. Additionally, having the inlet port 406 and the outlet port 408 on the same side face 418(1) reduces obstructions to a user handling the device 400 when the AMD 410 and the exit AMD 414 are outside the housing 404.

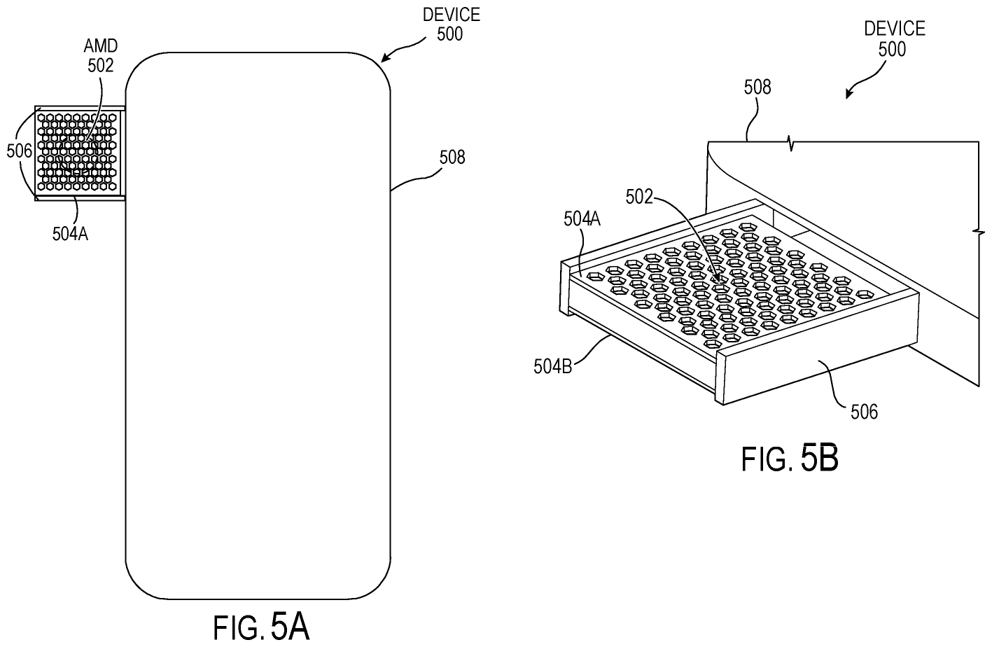

FIGS. 5A and 5B are views of another example of a device 500 including an AMD 502 in a second operating mode (pop-out mode) where protective grills 504A and 504B are included to reduce or avoid physical interference with moving parts of the AMD 502 by anything external to the device 500. For example, the protective grills 504A and 504B can reduce contact with a user's fingers, clothing, or hair, or with large airborne particles that could interfere with operation of fins, blades, or other moving parts of the AMD 502. The protective grills 504A and 504B may be attached to each side of a slide or carrier 506 that holds the AMD 502 and is employed to move the AMD 502 from inside a housing 508 in the first operating mode to a “pop-out” position in the second operating mode. Protective grills 504A, 504B may also be implemented on other AMDs having a pop-out mode, such as the exit AMD 414 in FIG. 4.

Electronic devices according to any aspects disclosed herein may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, laptop computer, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

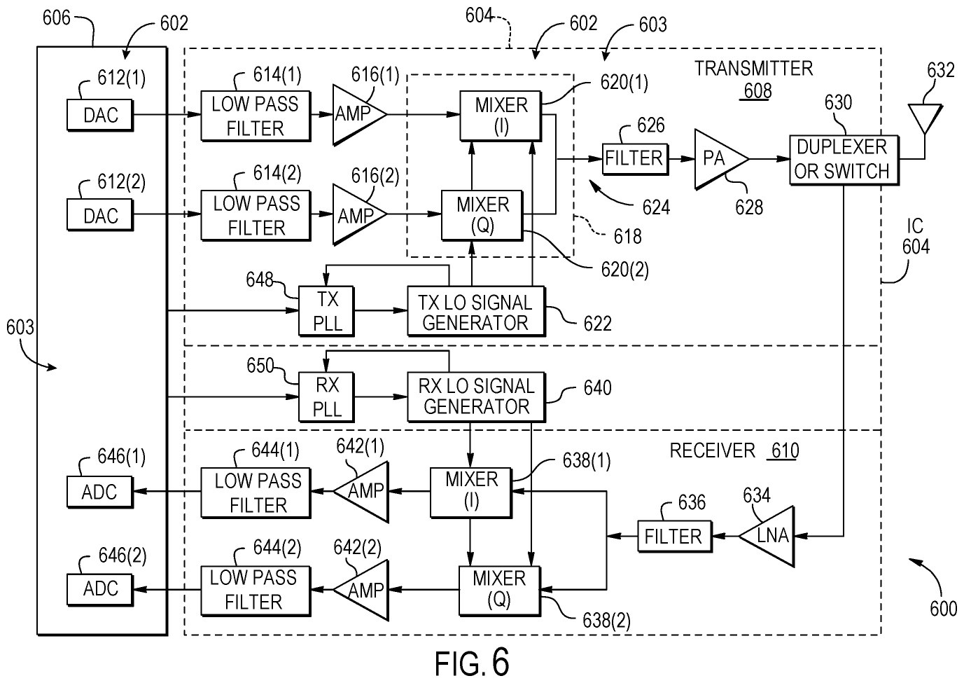

In this regard, FIG. 6 illustrates a block diagram of an exemplary wireless communications device 600 that includes radio frequency (RF) components formed from one or more ICs 602, wherein the communications device 600 may be any of the devices 100 and 400 as illustrated in FIGS. 1A, 1B, 2A, 2B, and 4 including one or more AMDs that may pop out of an airflow path to reduce impedance to airflow and provide increased cooling to one or more IC packages therein. The wireless communications device 600 may include or be provided as examples in any of the above-referenced devices. As shown in FIG. 6, the wireless communications device 600 includes a transceiver 604 and a data processor 606. The data processor 606 may include a memory to store data and program codes. The transceiver 604 includes a transmitter 608 and a receiver 610, which support bi-directional communications. In general, the wireless communications device 600 may include any number of transmitters 608 and/or receivers 610 for any number of communication systems and frequency bands. All or a portion of the transceiver 604 may be implemented on one or more analog ICs, RF ICs (RFICs), mixed-signal ICs, etc.

The transmitter 608 or the receiver 610 may be implemented with a super-heterodyne or direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 600 in FIG. 6, the transmitter 608 and the receiver 610 are implemented with the direct-conversion architecture.

In the transmit path, the data processor 606 processes data to be transmitted and provides I and Q analog output signals to the transmitter 608. In the exemplary wireless communications device 600, the data processor 606 includes digital-to-analog converters (DACs) 612(1), 612(2) for converting digital signals generated by the data processor 606 into I and Q analog output signals, e.g., I and Q output currents, for further processing.

Within the transmitter 608, lowpass filters 614(1), 614(2) filter the I and Q analog output signals, respectively, to remove undesired signals caused by the prior digital-to-analog conversion. Amplifiers (AMPs) 616(1), 616(2) amplify the signals from the lowpass filters 614(1), 614(2), respectively, and provide I and Q baseband signals. An upconverter 618 upconverts the I and Q baseband signals with I and Q transmit (TX) local oscillator (LO) signals from a TX LO signal generator 622 through mixers 620(1), 620(2) to provide an upconverted signal 624. A filter 626 filters the upconverted signal 624 to remove undesired signals caused by the frequency up conversion and noise in a receive frequency band. A power amplifier (PA) 628 amplifies the upconverted signal 624 from the filter 626 to obtain the desired output power level and provides a transmit RF signal. The transmit RF signal is routed through a duplexer or switch 630 and transmitted via an antenna 632.

In the receive path, the antenna 632 receives signals transmitted by base stations and provides a received RF signal, which is routed through the duplexer or switch 630 and provided to a low noise amplifier (LNA) 634. The duplexer or switch 630 is designed to operate with a specific receive (RX)-to-TX duplexer frequency separation, such that RX signals are isolated from TX signals. The received RF signal is amplified by the LNA 634 and filtered by a filter 636 to obtain a desired RF input signal. Down conversion mixers 638(1), 638(2) mix the output of the filter 636 with I and Q RX LO signals (i.e., LO_I and LO_Q) from an RX LO signal generator 640 to generate I and Q baseband signals. The I and Q baseband signals are amplified by AMPs 642(1), 642(2) and further filtered by lowpass filters 644(1), 644(2) to obtain I and Q analog input signals, which are provided to the data processor 606. In this example, the data processor 606 includes analog-to-digital converters (ADCs) 646(1), 646(2) for converting the analog input signals into digital signals to be further processed by the data processor 606.

In the wireless communications device 600 of FIG. 6, the TX LO signal generator 622 generates the I and Q TX LO signals used for frequency up conversion, while the RX LO signal generator 640 generates the I and Q RX LO signals used for frequency down conversion. Each LO signal is a periodic signal with a particular fundamental frequency. A TX phase-locked loop (PLL) circuit 648 receives timing information from the data processor 606 and generates a control signal used to adjust the frequency and/or phase of the TX LO signals from the TX LO signal generator 622. Similarly, an RX PLL circuit 650 receives timing information from the data processor 606 and generates a control signal used to adjust the frequency and/or phase of the RX LO signals from the RX LO signal generator 640.

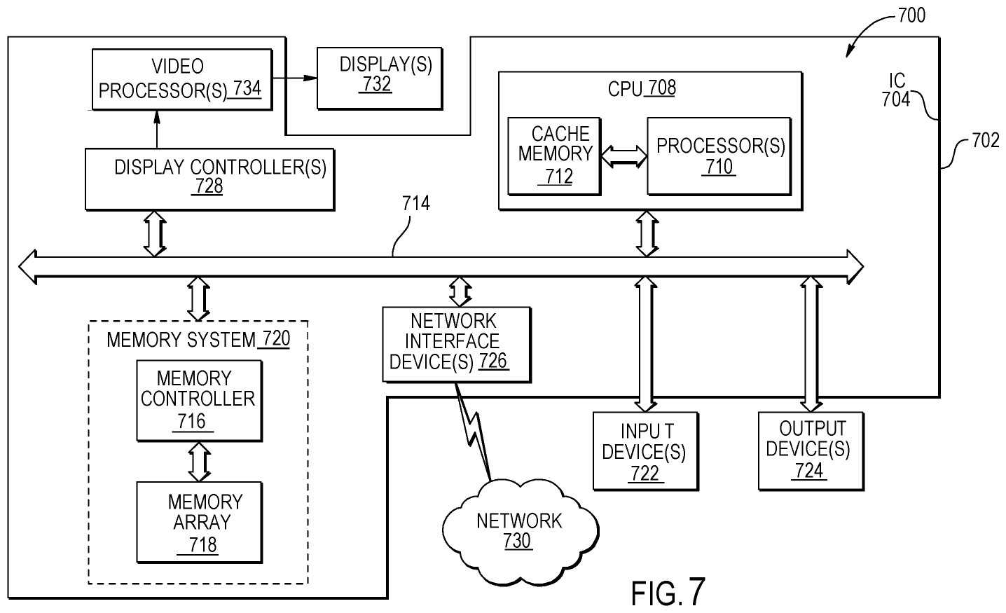

FIG. 7 illustrates a block diagram of an example of a processor-based system 700 that can employ integrated circuits and may be any of the devices 100 and 400 as illustrated in FIGS. 1A, 1B, 2A, 2B, and 4, including one or more AMDs that may pop out of an airflow path to reduce impedance to airflow and provide increased cooling to one or more IC packages therein, and according to the exemplary process in FIG. 3. In this example, the processor-based system 700 includes a processor 702 that includes an IC 704 including one or more central processor units (CPUs) 708, which may also be referred to as CPU or processor cores, each including one or more processors 710. The CPU(s) 708 may have cache memory 712 coupled to the processor(s) 702 for rapid access to temporarily stored data. The CPU(s) 708 is coupled to a system bus 714 and can intercouple master and slave devices included in the processor-based system 700. As is well known, the CPU(s) 708 communicates with these other devices by exchanging address, control, and data information over the system bus 714. For example, the CPU(s) 708 can communicate bus transaction requests to a memory controller 716 as an example of a slave device. Although not illustrated in FIG. 7, multiple system buses 714 could be provided wherein each system bus 714 constitutes a different fabric.

Other master and slave devices can be connected to the system bus 714. As illustrated in FIG. 7, these devices can include a memory system 720 that includes the memory controller 716 and one or more memory arrays 718, one or more input devices 722, one or more output devices 724, one or more network interface devices 726, and one or more display controllers 728, as examples. The input device(s) 722 can include any type of input device, including, but not limited to, input keys, switches, voice processors, etc. The output device(s) 724 can include any type of output device, including, but not limited to, audio, video, other visual indicators, etc. The network interface device(s) 726 can be any device configured to allow an exchange of data to and from a network 730. The network 730 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 726 can be configured to support any type of communications protocol desired.

The CPU(s) 708 may also be configured to access the display controller(s) 728 over the system bus 714 to control information sent to one or more displays 732. The display controller(s) 728 sends information to the display(s) 732 to be displayed via one or more video processors 734, which process the information to be displayed into a format suitable for the display(s) 732. The display(s) 732 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium wherein any such instructions are executed by a processor or other processing device, or combinations of both. As examples, the devices and components described herein may be employed in any circuit, hardware component, integrated circuit (IC), or IC chip. Memory disclosed herein may be any type and size of memory and may be configured to store any desired information. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

Implementation examples are described in the following numbered clauses:
1. A device comprising:
   a housing;
   at least one integrated circuit (IC) package disposed inside the housing; and
   a first air-moving device (AMD) configured to move air through the housing;
   wherein:
      in a first operating mode, the first AMD is disposed inside the housing; and
      in a second operating mode, the first AMD is disposed at least partially outside the housing.
2. The device of clause 1, the housing further comprising:
   a first face and a second face opposite to each other; and
   a first side face between the first face and the second face;
   wherein the first AMD is disposed outside the first side face in the second operating mode.
3. The device of clause 1 or clause 2, configured to transition between the first operating mode and the second operating mode in response to a detected temperature inside the housing.
4. The device of clause 1 or clause 2, configured to transition between the first operating mode and the second operating mode in response to a user contact.
5. The device of clause 1 or clause 2, configured to transition between the first operating mode and the second operating mode in response to an instruction executed in the IC package.
6. The device of any of clause 1 to clause 5, wherein the first AMD comprises a fan configured to rotate in a plane that extends through the housing in the first operating mode and in the second operating mode.
7. The device of any of clause 1 to clause 6, further comprising at least one first protective grill configured to protect the fan from physical interference.
8. The device of any of clause 1 to clause 7, wherein, in the second operating mode, the AMD is entirely outside the housing.
9. The device of any of clause 2 to clause 8, the housing further comprising an airflow path extending from an inlet port in the first side face and through the housing to an outlet port.
10. The device of clause 9, further comprising a heat sink comprising fins disposed in the airflow path.
11. The device of clause 9 or clause 10, wherein the outlet port is disposed in a second side face of the housing opposite to the first side face.
12. The device of clause 9 or clause 10, wherein the outlet port is disposed in the first side face of the housing.
13. The device of any of clause 9 to clause 12, further comprising:
   at least one exit AMD disposed adjacent to the outlet port and configured to move air from the airflow path out of the housing through the outlet port.
14. The device of clause 13, wherein the at least one exit AMD is disposed inside the housing in the first operating mode and outside the housing in the second operating mode.
15. The device of clause 13 or clause 14, wherein:
   the at least one exit AMD comprises at least two exit AMDs disposed adjacent to the outlet port and configured to move air from the airflow path out of the housing through the outlet port.
16. The device of any of clause 1 to clause 15, wherein:
   the AMD is configured to move through an inlet port to transition between the first operating mode and the second operating mode.
17. The device of any of clause 1 to clause 16, wherein:
   the first face of the housing comprises a rectangular shape comprising longer sides and shorter sides; and the first side face comprises one of the longer sides.
18. The device of clause 17, wherein:
   the longer sides have a first length in a range from 4 inches to 12 inches; and the shorter sides have a second length in a range from 2 inches to 9 inches.
19. The device of any of clause 2 to clause 18, the first face comprising a video display.
20. The device of any of clause 1 to clause 19 comprising a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.
21. A method of cooling a device, the device comprising:
   at least one integrated circuit package in a housing; and
   a first air-moving device (AMD) configured to move air through a first side face;
   wherein the method comprises:
      in a first operating mode, activating the AMD inside the housing; and
      in a second operating mode, moving the AMD at least partially outside the housing.
22. A smartphone comprising:
   a housing comprising:
      a front face and a back face opposite to each other; and
      a first side face between a first edge of the front face and a second edge of the back face;
   at least one integrated circuit (IC) package disposed inside the housing, the IC package comprising a processor configured to execute user applications; and
   a first air-moving device (AMD) configured to move air through the first side face;
   wherein:
      in a first operating mode, the first AMD is disposed inside the housing; and
      in a second operating mode, the first AMD is disposed at least partially outside the housing.

What is claimed is:

1. A device comprising:
a housing;
at least one integrated circuit (IC) package disposed inside the housing; and
a first air-moving device (AMD) configured to move air through the housing;
wherein:
in a first operating mode, the first AMD is disposed inside the housing; and
in a second operating mode, the first AMD is disposed at least partially outside the housing.

2. The device of claim 1, the housing further comprising:
a first face and a second face opposite to each other; and
a first side face between the first face and the second face;
wherein the first AMD is disposed outside the first side face in the second operating mode.

3. The device of claim 1, configured to transition between the first operating mode and the second operating mode in response to a detected temperature inside the housing.

4. The device of claim 1, configured to transition between the first operating mode and the second operating mode in response to a user contact.

5. The device of claim 1, configured to transition between the first operating mode and the second operating mode in response to an instruction executed in the IC package.

6. The device of claim 1, wherein:
the first AMD comprises a fan configured to rotate in a plane that extends through the housing in the first operating mode and in the second operating mode.

7. The device of claim 6, further comprising at least one first protective grill configured to protect the fan from physical interference.

8. The device of claim 1, wherein, in the second operating mode, the AMD is entirely outside the housing.

9. The device of claim 2, the housing further comprising an airflow path extending from an inlet port in the first side face and through the housing to an outlet port.

10. The device of claim 9, further comprising a heat sink comprising fins disposed in the airflow path.

11. The device of claim 9, wherein the outlet port is disposed in a second side face of the housing opposite to the first side face.

12. The device of claim 9, wherein the outlet port is disposed in the first side face of the housing.

13. The device of claim 9, further comprising:
at least one exit AMD disposed adjacent to the outlet port and configured to move air from the airflow path out of the housing through the outlet port.

14. The device of claim 13, wherein the at least one exit AMD is disposed inside the housing in the first operating mode and outside the housing in the second operating mode.

15. The device of claim 13, wherein:
the at least one exit AMD comprises at least two exit AMDs disposed adjacent to the outlet port and configured to move air from the airflow path out of the housing through the outlet port.

16. The device of claim 1, wherein:
the AMD is configured to move through an inlet port to transition between the first operating mode and the second operating mode.

17. The device of claim 2, wherein:
the first face of the housing comprises a rectangular shape comprising longer sides and shorter sides; and
the first side face comprises one of the longer sides.

18. The device of claim 17, wherein:
the longer sides have a first length in a range from 4 inches to 12 inches; and
the shorter sides have a second length in a range from 2 inches to 9 inches.

19. The device of claim 2, the first face comprising a video display.

20. The device of claim 1 comprising a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; an avionics system; a drone; and a multicopter.

21. A method of cooling a device, the device comprising:
at least one integrated circuit package in a housing; and
a first air-moving device (AMD) configured to move air through a first side face;
wherein the method comprises:
in a first operating mode, activating the AMD inside the housing; and
in a second operating mode, moving the AMD at least partially outside the housing.

22. A smartphone comprising:
a housing comprising:
a front face and a back face opposite to each other; and
a first side face between a first edge of the front face and a second edge of the back face;
at least one integrated circuit (IC) package disposed inside the housing, the IC package comprising a processor configured to execute user applications; and
a first air-moving device (AMD) configured to move air through the first side face;
wherein:
in a first operating mode, the first AMD is disposed inside the housing; and
in a second operating mode, the first AMD is disposed at least partially outside the housing.
